(19) United States
(12) Patent Application Publication
(10) Pub. No.: US 2024/0243159 A1
(43) Pub. Date: Jul. 18, 2024

(54) IMAGE SENSOR AND MANUFACTURING METHOD THEREOF

(71) Applicant: ELECTRONICS AND TELECOMMUNICATIONS RESEARCH INSTITUTE, Daejeon (KR)

(72) Inventors: Jeong Woo PARK, Daejeon (KR); Sang Hoon KIM, Daejeon (KR); Dongwoo SUH, Daejeon (KR)

(21) Appl. No.: 18/535,731

(22) Filed: Dec. 11, 2023

(30) Foreign Application Priority Data
Jan. 13, 2023 (KR) 10-2023-0005165

(51) Int. Cl. H01L 27/146

(52) U.S. Cl. CPC H01L 27/14649; H01L 27/14636; H01L 27/14683

(57) ABSTRACT

The present disclosure relates to an image sensor including a silicon substrate having a first conductivity type, and a read out integrated circuit (ROIC) and a photodetector disposed on the silicon substrate. The ROIC and the photodetector are spaced apart from each other in a first direction parallel to a top surface of the silicon substrate. The photodetector includes a first germanium pattern having the first conductivity type and a semiconductor pattern having a second conductivity type different from the first conductivity type, which are laminated in a direction perpendicular to the top surface of the silicon substrate. The first germanium pattern contacts the silicon substrate.

### CROSS-REFERENCE TO RELATED APPLICATION

This U.S. non-provisional patent application claims priority under 35 U.S.C. § 119 of Korean Patent Application No. 10-2023-0005165, filed on Jan. 13, 2023, the entire contents of which are hereby incorporated by reference.

### BACKGROUND

The present disclosure relates to an image sensor and a manufacturing method thereof, and more particularly, to an image sensor that acquires an image in a short-wave infrared band and a manufacturing method thereof.

Image sensors capable of detecting images by using infrared (IR), particularly short wavelength IR, are important in a wide range of applications including optical communications, laser detection and ranging (LADAR), and medicine preparation. The sensors are also used in technology conservation, detection of tumors, astronomy, imaging through smoke and clouds, detection of pollution, infrared microscopy, infrared telescopes, and integrated circuit manufacturing. The infrared image sensors are core components of three-dimensional laser detection and ranging (3-D LADAR) and night vision equipment.

A typical image sensor includes photodetectors in a two-dimensional array combined with a read out integrated circuit (ROIC). The photodetectors are sensitive to incident light. The ROIC quantitatively evaluates outputs from the photodetectors and processes the outputs into images.

Typically, the ROIC and the photodetectors in the two-dimensional array constitute separate respective chips, and the image sensor is driven by connecting the chips. When flip chip bonding is performed for connecting the two chips, a highly sophisticated hybrid integration technology is required because a pad has a micrometer size and the number of the pads exceeds one million, and thus productivity is not high.

### SUMMARY

The present disclosure provides an image sensor in which a read out integrated circuit (ROIC) and a photodetector are integrated into a single chip to improve productivity.

An embodiment of the inventive concept provides an image sensor including: a silicon substrate having a first conductivity type; and a read out integrated circuit (ROIC) and a photodetector on the silicon substrate, in which the ROIC and the photodetector are spaced apart from each other in a first direction parallel to a top surface of the silicon substrate, the photodetector includes a first germanium pattern having the first conductivity type and a semiconductor pattern having a second conductivity type different from the first conductivity type, which are laminated in a direction perpendicular to the top surface of the silicon substrate, and the first germanium pattern contacts the silicon substrate.

In an embodiment, the semiconductor pattern may be a germanium pattern, and the semiconductor pattern may contact the first germanium pattern.

In an embodiment, the photodetector may further include a second germanium pattern disposed between the first germanium pattern and the semiconductor pattern, the second germanium pattern may contact the first germanium pattern and the semiconductor pattern, and the semiconductor pattern may be a silicon pattern.

In an embodiment, the image sensor may further include an intrinsic silicon layer disposed on the silicon substrate, and the ROIC may be disposed at an upper portion of the silicon layer.

In an embodiment, the silicon layer may include a trench configured to expose the top surface of the silicon substrate, and the photodetector may be disposed in the trench.

In an embodiment, the image sensor may further include a line layer disposed on the ROIC and the photodetector.

In an embodiment of the inventive concept, an image sensor includes: a silicon substrate having a first conductivity type; an intrinsic silicon layer disposed on the silicon substrate, in which the silicon layer includes a trench passing through the silicon layer; a read out integrated circuit (ROIC) disposed at an upper portion of the silicon layer; a photodetector and a buried insulation pattern disposed in the trench; and metal lines disposed on the photodetector and the ROIC. Here, the photodetector includes a first germanium pattern having a first conductivity type and a semiconductor pattern having a second conductivity type different from the first conductivity type, which are vertically laminated with each other. Also, the buried insulation pattern is disposed between the photodetector and the silicon layer to expose a top surface of the silicon substrate.

In an embodiment, the semiconductor pattern may be a germanium pattern, and the semiconductor pattern may contact the first germanium pattern.

In an embodiment, the photodetector may further include a second germanium pattern disposed between the first germanium pattern and the semiconductor pattern, the second germanium pattern may contact the first germanium pattern and the semiconductor pattern, and the semiconductor pattern may be a silicon pattern.

In an embodiment, the image sensor may further include a mask pattern disposed on the silicon layer, and the mask pattern may include an opening that vertically overlaps the trench.

In an embodiment, each of the mask pattern and the buried insulation pattern may include a silicon oxide.

In an embodiment of the inventive concept, a method for manufacturing an image sensor includes: preparing a silicon substrate having a first conductivity type surface; forming an intrinsic silicon layer disposed on the silicon substrate; forming a read out integrated circuit (ROIC) in the intrinsic silicon layer; forming a trench configured to expose a top surface of the silicon substrate in the intrinsic silicon layer; and forming a photodetector in the trench, in which the forming of the photodetector includes sequentially forming a first germanium pattern having a first conductivity type and a second germanium pattern having a second conductivity type in the trench.

In an embodiment, the forming of the germanium pattern having the first conductivity type may include epitaxially growing on the silicon substrate having the first conductivity type.

In an embodiment, the forming of the trench configured to expose the top surface of the silicon substrate in the intrinsic silicon layer includes: forming a mask pattern including an opening on the silicon layer; and performing an etching process by using the mask pattern as an etching mask.

In an embodiment, the method may further include: before the forming of the first germanium pattern having the first conductivity type, forming an insulation layer configured to cover an inner wall and a bottom surface of the trench; and removing a portion of the insulation layer, which vertically overlaps the bottoms surface of the trench.

In an embodiment, the forming of the semiconductor pattern having the second conductivity type may include injecting impurities in an in-situ process, and the semiconductor pattern contacts the first germanium pattern.

In an embodiment, the forming of the photodetector may further include forming an intrinsic second germanium pattern on the first germanium pattern before the forming of the semiconductor pattern, and the semiconductor pattern may be a silicon pattern.

In an embodiment, the method may further include forming metal lines configured to connect the ROIC and the photodetector.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a schematic cross-sectional view illustrating an image sensor according to an embodiment of the inventive concept;

FIG. 1B is a schematic cross-sectional view illustrating an image sensor according to some embodiments; and

FIG. 2A, FIG. 2B, FIG. 2C, FIG. 2D, FIG. 2E, and FIG. 2F are cross-sectional views illustrating a manufacturing process of an image sensor according to an embodiment of the inventive concept.

### DETAILED DESCRIPTION

Preferred embodiments of the inventive concept will be described with reference to the accompanying drawings so as to sufficiently understand constitutions and effects of embodiments of the inventive concept. The technical ideas of the inventive concept may however, be embodied in different forms and should not be construed as limited to the embodiments set forth herein. Rather, these embodiments are provided so that this disclosure will be thorough and complete, and will fully convey the scope of the present invention to those skilled in the art. In the accompanying drawings, the dimensions of layers and regions are exaggerated for clarity of illustration.

Unless otherwise specifically defined herein, all terms including technical or scientific terms are to be given meanings understood by those skilled in the art. Hereinafter, preferred embodiments of the inventive concept will be described in detail with reference to the attached drawings.

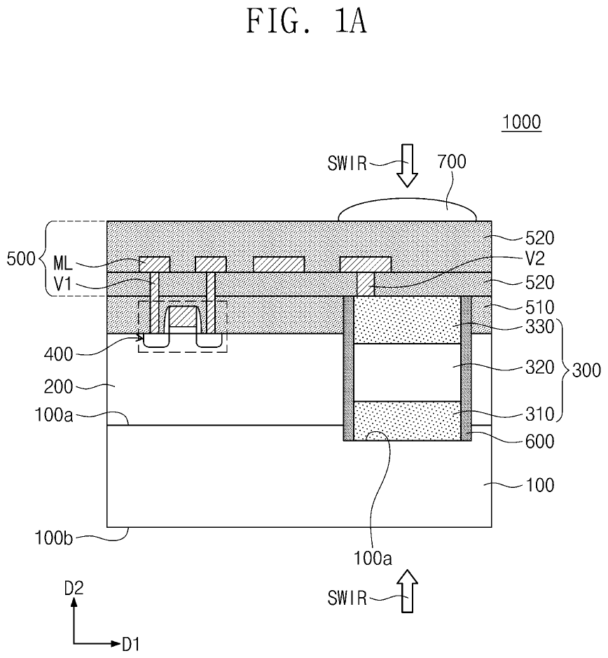

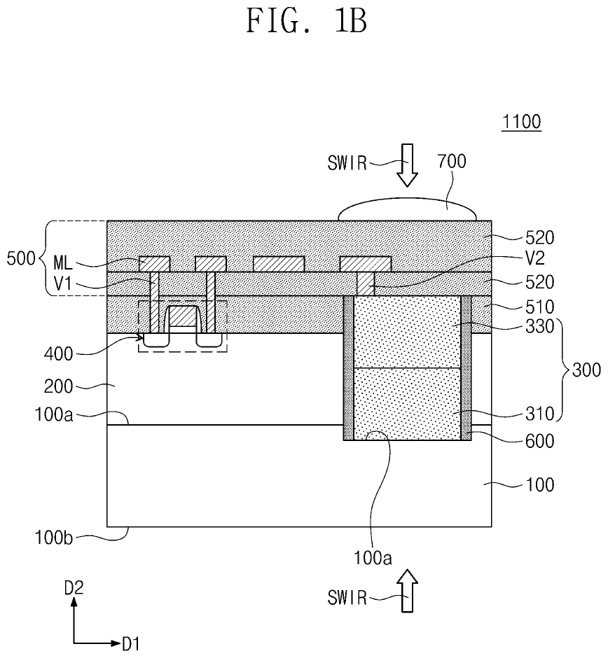

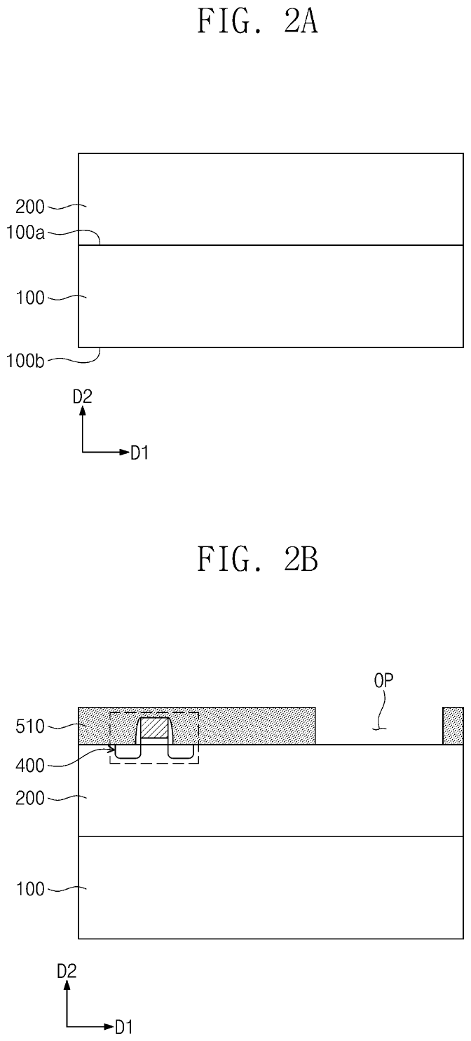

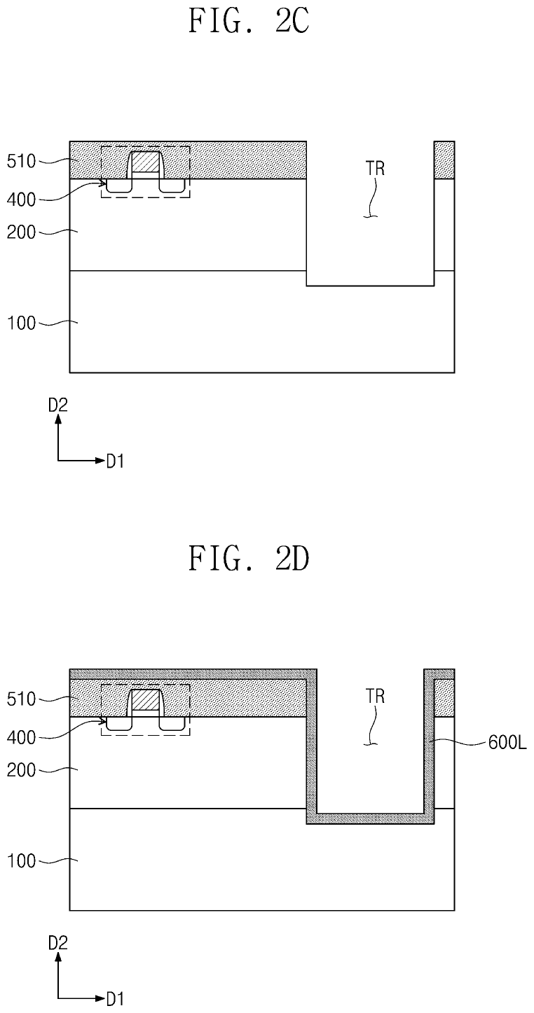

FIG. 1A is a schematic cross-sectional view illustrating an image sensor according to an embodiment of the inventive concept.

Referring to FIG. 1A, an image sensor 1000 may include a silicon substrate 100 having a first conductivity type on a surface thereof, an intrinsic silicon layer 200, a read out integrated circuit (ROIC) 400, a photodetector 300, and a line layer 500, and a micro-lens 700.

The first conductivity type may be a p-type or an n-type. The silicon substrate 100 may have a first surface 100a and a second surface 100b, which face each other.

The intrinsic silicon layer 200 may be disposed on the first surface 100a of the silicon substrate 100. The first surface 100a may contact the intrinsic silicon layer 200. On the contrary, the second surface 100b may be spaced apart from the intrinsic silicon layer 200. In this specification, a direction parallel to the first surface 100a is defined as a first direction D1, and a direction perpendicular to the first surface 100a is defined as a second direction D2. In this specification, a term of intrinsic represents that a doping process is not performed or that there are substantially no impurities.

The read out integrated circuit (ROIC) 400 may be disposed at an upper portion of the silicon layer 200. The ROIC 400 may include an active device such as a transistor and a bipolar device. The ROIC 400 may be applied depending on a design purpose among known ROICs.

A mask pattern 510 may be disposed on the silicon layer 200. The mask pattern 510 may cover the ROIC 400. The mask pattern 510 may include, e.g., a silicon oxide (SiOₓ).

Each of the mask pattern 510 and the silicon layer 200 may include a trench that exposes the first surface 100a of the silicon substrate 100. The trench may be defined by an inner wall of the mask pattern 510, an inner wall of the silicon layer 200, and the first surface 100a of the silicon substrate 100 exposed from the silicon layer 200. Alternatively, as illustrated in FIG. 1A, the trench may be defined by the inner wall of the mask pattern 510, the inner wall of the silicon layer 200, an inner wall of the silicon substrate 100, and the first surface 100a of the silicon substrate 100 exposed from the silicon layer 200.

The photodetector 300 may be disposed in the trench. The photodetector 300 may have, e.g., a vertical PIN diode structure. The photodetector 300 may be spaced apart from the ROIC 400 in the first direction D1. The photodetector 300 according to an embodiment of the inventive concept may be provided in plurality as an array having a matrix form of M×N (M and N are natural numbers equal to or greater than 1).

The photodetector 300 may include a first conductivity type first germanium pattern 310 having a first conductivity type, an intrinsic second germanium pattern 320, and a semiconductor pattern 330 having a second conductivity type, which are sequentially laminated in the second direction D2. The intrinsic second germanium pattern 320 may serve as a light absorption layer. The semiconductor pattern 330 may include a material different from germanium. The semiconductor pattern 330 may be, e.g., a silicon pattern. The silicon substrate 100 and the first germanium pattern 310 may have the same conductivity type. The first surface 100a of the silicon substrate 100 may contact a bottom surface of the first germanium pattern 310. The germanium pattern 310 having the first conductivity type may be epitaxially grown on the silicon substrate 100 having the first conductivity type.

For example, when the first conductivity type is a p-type, the photodetector 300 may include a p-type first germanium pattern 310, an intrinsic second germanium pattern 320, and an n-type silicon pattern 330 in the second direction D2. In this case, the silicon substrate 100 may also have a p-type. As another example, when the first conductivity type is an n-type, the photodetector 300 may include an n-type first germanium pattern 310, an intrinsic second germanium pattern 320, and a p-type silicon pattern 330 in the second direction D2. In this case, the silicon substrate 100 may also have an n-type.

A buried insulation pattern 600 may be disposed between the photodetector 300 and the mask pattern 510 and between the silicon layer 200 and the silicon substrate 100. The buried insulation pattern 600 may cover the inner wall of the mask pattern 510, the inner wall of the silicon layer 200, and the inner wall of the silicon substrate 100 while exposing the first surface 100a of the silicon substrate 100. Each of the buried insulation patterns 600 may include, e.g., a silicon oxide.

The line layer 500 may be disposed on the ROIC 400 and the photodetector 300. The line layer 500 may include vias V1 and V2 and metal lines ML connected to the vias. The vias V1 and V2 may include a first via V1 and a second via V2. For example, the first via V1 may be electrically connected to the ROIC 400, and the second via V2 may be electrically connected to the photodetector 300. The ROIC 400 and the photodetector 300 may be electrically connected to each other through the vias V1 and V2 and the metal lines ML connected to the vias. The line layer 500 may further include insulation layers 520, and the vias V1 and V2 and the metal lines ML may be disposed between the insulation layers 520.

The micro-lens 700 may be disposed on the line layer 500. The micro-lens 700 may overlap the photodetector 300 in the second direction D2. The micro-lens 700 may include, e.g., polyimide.

According to an embodiment of the inventive concept, a single-chip image sensor including a silicon-based ROIC and a germanium photodetector array on a single silicon substrate may be realized. The germanium photodetector may react to light in a wavelength range of 1 μm to 1.6 μm and generate current. For example, when the image sensor according to an embodiment of the inventive concept is applied to a camera of a car being driven, visibility may be secured in a situation (night, fog, etc.) which is invisible to human eyes.

The image sensor according to an embodiment of the inventive concept may perform all of front side illumination and back side illumination. When short wavelength infrared SWIR is incident toward the second surface 100b of the silicon substrate 100, the short wavelength infrared SWIR may be transmitted to the photodetector 300 without loss because the silicon substrate 100 has a small absorption of the short wavelength infrared SWIR. Also, the short wavelength infrared SWIR may pass through the micro-lens 700 and reach the second germanium pattern 320 that serves as a light absorption layer. In this case, since the semiconductor pattern 330 includes silicon, the short wavelength infrared SWIR may reach the light absorption layer without loss in comparison with a case of using germanium.

FIG. 1B is a schematic cross-sectional view illustrating an image sensor according to some embodiments. Hereinafter, descriptions overlapped with those described in FIG. 1A will be omitted.

Referring to FIG. 1B, an image sensor 1100 may include a photodetector 300 having a vertical PN diode structure.

The photodetector 300 may not include an intrinsic second germanium pattern 320.

The photodetector 300 may include a first germanium pattern 310 having a first conductivity type and a semiconductor pattern 330. The semiconductor pattern 330 having a second conductivity type may be, e.g., a second germanium pattern. That is, when the first conductive type is a p-type, the photodetector 300 may include the p-type first germanium pattern 310 and the n-type second germanium pattern 330, which are sequentially arranged in the second direction D2. That is, when the first conductive type is a p-type, the photodetector 300 may include the p-type first germanium pattern 310 and the n-type second germanium pattern 330, which are sequentially arranged in the second direction D2.

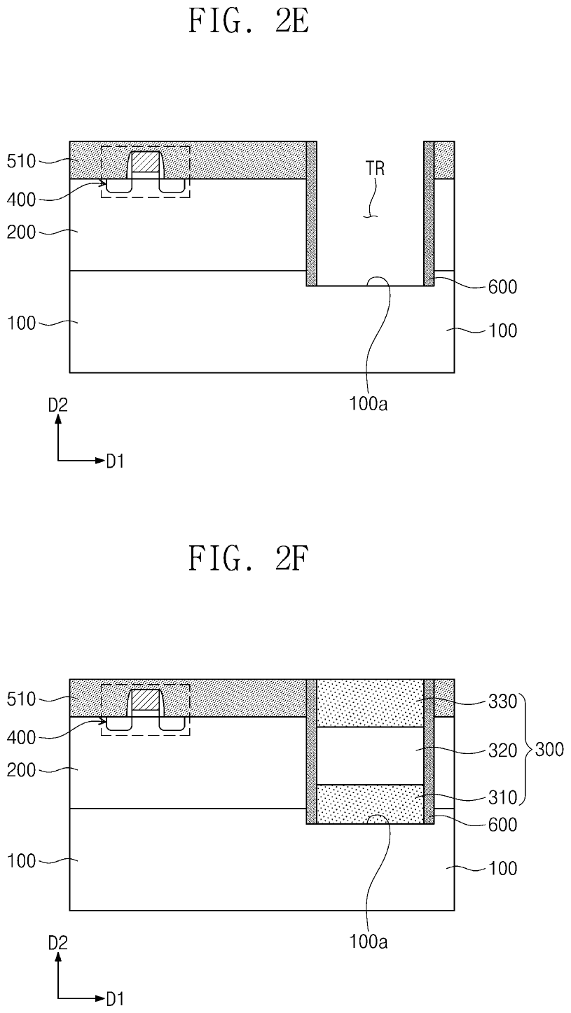

FIGS. 2A to 2F are cross-sectional views illustrating a manufacturing process of an image sensor according to an embodiment of the inventive concept.

Referring to FIG. 2A, a silicon substrate 100 having a first conductivity type may be prepared. A doping process of impurities may be performed on the silicone substrate 100 so that the entire silicon substrate 100 has a conductivity type. An intrinsic silicon layer 200 may be disposed on a first surface 100a of the silicon substrate 100. The silicon layer 200 may be formed by, e.g., well-known epitaxial growth.

Referring to FIG. 2B, a read out integrated circuit (ROIC) 400 may be formed on the silicon layer 200. Thereafter, a mask pattern 510 including an opening OP may be formed on the ROIC 400. The opening OP may define a space in which a trench TR of FIG. 2C is formed.

Referring to FIG. 2C, the trench TR may be formed by performing a first etching process. Specifically, the first etching process may be performed by using the mask pattern 510 as an etching mask. The first etching process may be performed until the silicone layer 200 is etched and the first surface 100a of the silicon substrate 100 is exposed. Here, a portion of the silicon substrate 100 may be also etched.

Referring to FIG. 2D, a buried insulation layer 600L may cover the mask pattern 510 and an inner wall and a bottom surface of the trench TR. The buried insulation layer 600L may be conformally formed.

Referring to FIG. 2E, a buried insulation pattern 600 may be formed by performing an etch back process of the buried insulation layer 600L. In the buried insulation layer 600L, a portion vertically overlapping the mask pattern 510 and a portion vertically overlapping the first face 100a of the silicon substrate 100 in the second direction D2 may be selectively removed. As a result of the etch back process, the buried insulation pattern 600 may be formed.

Referring to FIG. 2F, the photodetector 300 may be formed such that a first germanium pattern 310 having a first conductivity type, an intrinsic germanium pattern 320, and a semiconductor pattern 330 having a second conductivity type are sequentially formed by selective epitaxial growth. The first germanium pattern 310 and the semiconductor pattern 320 may be formed by an in-situ method.

When the first germanium pattern 310 is formed directly on the intrinsic silicon substrate, a dislocation caused by a lattice mismatch increases, and thus, dark current of the image sensor may be generated. According to an embodiment of the inventive concept, the first germanium pattern 310 having the first conductivity type may be directly formed on the silicone substrate 100 having the first conductivity type.

Referring to FIG. 1A again, a plurality of insulation layers 520, vias V1 and V2, and metal lines ML may be formed to constitute a line layer 500. Thereafter, a micro-lens 700 may be formed on the line layer 500.

According to an embodiment of the inventive concept, a single-chip image sensor including a silicon-based ROIC and a germanium photodetector array on a single silicon substrate may be realized. As a result, reliability may increase during mass production in comparison with a case of bonding two chips. Also, according to an embodiment of the inventive concept, a germanium pattern having a first conductivity type may be directly formed on a silicon substrate having a first conductivity type. Also, the silicon substrate may be used as an electrode.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed. Thus, the above-disclosed embodiments are to be considered illustrative and not restrictive.

What is claimed is:

1. An image sensor comprising:
a silicon substrate having a first conductivity type; and
a read out integrated circuit (ROIC) and a photodetector on the silicon substrate,
wherein the ROIC and the photodetector are spaced apart from each other in a first direction parallel to a top surface of the silicon substrate,
the photodetector comprises a first germanium pattern having the first conductivity type and a semiconductor pattern having a second conductivity type different from the first conductivity type, which are laminated in a direction perpendicular to the top surface of the silicon substrate, and
the first germanium pattern contacts the silicon substrate.

2. The image sensor of claim 1, wherein the semiconductor pattern is a germanium pattern, and
the semiconductor pattern contacts the first germanium pattern.

3. The image sensor of claim 1, wherein the photodetector further comprises a second germanium pattern disposed between the first germanium pattern and the semiconductor pattern,
the second germanium pattern contacts the first germanium pattern and the semiconductor pattern, and
the semiconductor pattern is a silicon pattern.

4. The image sensor of claim 1, further comprising an intrinsic silicon layer disposed on the silicon substrate,
wherein the ROIC is disposed at an upper portion of the silicon layer.

5. The image sensor of claim 4, wherein the silicon layer comprises a trench configured to expose the top surface of the silicon substrate, and
the photodetector is disposed in the trench.

6. The image sensor of claim 1, further comprising a line layer disposed on the ROIC and the photodetector.

7. An image sensor comprising:
a silicon substrate having a first conductivity type;
an intrinsic silicon layer disposed on the silicon substrate, wherein the silicon layer comprises a trench passing through the silicon layer;
a read out integrated circuit (ROIC) disposed at an upper portion of the silicon layer;
a photodetector and a buried insulation pattern disposed in the trench; and
metal lines disposed on the photodetector and the ROIC,
wherein the photodetector comprises a first germanium pattern having a first conductivity type and a semiconductor pattern having a second conductivity type different from the first conductivity type, which are vertically laminated with each other,
wherein the buried insulation pattern is disposed between the photodetector and the silicon layer to expose a top surface of the silicon substrate.

8. The image sensor of claim 7, wherein the semiconductor pattern is a germanium pattern, and
the semiconductor pattern contacts the first germanium pattern.

9. The image sensor of claim 7, wherein the photodetector further comprises a second germanium pattern disposed between the first germanium pattern and the semiconductor pattern,
the second germanium pattern contacts the first germanium pattern and the semiconductor pattern, and
the semiconductor pattern is a silicon pattern.

10. The image sensor of claim 7, further comprising a mask pattern disposed on the silicon layer,
wherein the mask pattern comprises an opening that vertically overlaps the trench.

11. The image sensor of claim 10, wherein each of the mask pattern and the buried insulation pattern comprises a silicon oxide.

12. A method for manufacturing an image sensor, comprising:
preparing a silicon substrate having a first conductivity type surface;
forming an intrinsic silicon layer disposed on the silicon substrate;
forming a read out integrated circuit (ROIC) in the intrinsic silicon layer;
forming a trench configured to expose a top surface of the silicon substrate in the intrinsic silicon layer; and
forming a photodetector in the trench,
wherein the forming of the photodetector comprises sequentially forming a first germanium pattern having a first conductivity type and a second germanium pattern having a second conductivity type in the trench.

13. The method of claim 12, wherein the forming of the germanium pattern having the first conductivity type comprises epitaxially growing on the silicon substrate having the first conductivity type.

14. The method of claim 12, wherein the forming of the trench configured to expose the top surface of the silicon substrate in the intrinsic silicon layer comprises:
forming a mask pattern comprising an opening on the silicon layer; and
performing an etching process by using the mask pattern as an etching mask.

15. The method of claim 12, further comprising: before the forming of the first germanium pattern having the first conductivity type,
forming an insulation layer configured to cover an inner wall and a bottom surface of the trench; and
removing a portion of the insulation layer, which vertically overlaps the bottoms surface of the trench.

16. The method of claim 12, wherein the forming of the semiconductor pattern having the second conductivity type comprises injecting impurities in an in-situ process, and
the semiconductor pattern contacts the first germanium pattern.

17. The method of claim 12, wherein the forming of the photodetector further comprises forming an intrinsic second germanium pattern on the first germanium pattern before the forming of the semiconductor pattern, and
the semiconductor pattern is a silicon pattern.

18. The method of claim 12, further comprising forming metal lines configured to connect the ROIC and the photodetector.
